(19) United States
(12) Patent Application Publication
(10) Pub. No.: US 2025/0191640 A1
(43) Pub. Date: Jun. 12, 2025

(54) APPARATUSES AND METHODS FOR ACCESS OPERATIONS DURING VOLTAGE TRANSITION

(71) Applicant: Micron Technology, Inc., Boise, ID (US)

(72) Inventors: HIROKI TAKAHASHI, Tokyo (JP); OSAMU NAGASHIMA, Sagamihara (JP); SHUNICHI SAITO, Sagamihara (JP)

(73) Assignee: Micron Technology, Inc., Boise, ID (US)

(21) Appl. No.: 18/951,246

(22) Filed: Nov. 18, 2024

Related U.S. Application Data
(60) Provisional application No. 63/608,929, filed on Dec. 12, 2023.

(51) Int. Cl. G11C 11/4076; G11C 11/4096

(52) U.S. Cl. CPC G11C 11/4076; G11C 11/4096

(57) ABSTRACT

Apparatuses, systems, and methods for access operations during a voltage transition. A memory may receive a system voltage and a clock signal from a controller. The controller may be used to time operations such as write operations however, an internal clock signal of the memory may be dependent on the voltage. The memory operates at a double data rate relative to the clock signal. During a transition period while the voltage changes between levels, the memory may switch to a transition mode where the memory operates at a single data rate.

### CROSS-REFERENCE TO RELATED APPLICATIONS

This application claims the filing benefit of U.S. Provisional Application No. 63/608,929, filed Dec. 12, 2023.

### BACKGROUND

This disclosure relates generally to semiconductor devices, and more specifically to semiconductor memory devices. In particular, the disclosure relates to volatile memory, such as dynamic random access memory (DRAM). Information may be stored on individual memory cells of the memory as a physical signal (e.g., a charge on a capacitive element). During an example access operation, such as a read or write operation, data is sent/received across data terminals of the memory device in synchronization with a clock signal.

Memory devices may operate based on various system voltages provided to external terminals of the memory. Certain devices may operate in different modes (e.g., a normal mode and a low power mode) where different levels of the external voltage are used. However, varying the voltage may also change the frequency of the clock signal. There may be a need to prevent errors caused by a mismatch between the changing clock signal frequency and the data.

### BRIEF DESCRIPTION OF THE DRAWINGS

FIG. 1 is a block diagram of a semiconductor device according an embodiment of the disclosure.

FIG. 2 is a block diagram of a write path according to some embodiments of the present disclosure.

FIG. 3 is a timing chart of a voltage transition mode according to some embodiments of the present disclosure.

FIG. 4 is a flow chart of a method of a voltage transition mode according to some embodiments of the present disclosure.

FIG. 5 is a flow chart of a method of accessing a memory during a transition mode according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part thereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Memory arrays may generally include a number of memory cells arranged at the intersection of word lines (rows) and bit lines/digit lines (columns). During a write operation, the device receives data along data terminals. The data is then written to a word line specified by a row address and to bit lines selected by a column address. During a read operation, the data is read out to the terminals. The data may be transmitted across the terminals in synchronization with an associate data clock, such as a write clock during a write operation.

The write clock may be received at an external terminal of the memory device and passed through one or more buffer circuits to generate an internal write clock signal. The buffer circuits may be, at least partially, dependent on an external system voltage supplied to the memory. Memory devices may have multiple modes (e.g., a normal and low power mode) which include different voltages received as the system voltage. Because the internal write clock passes through buffers dependent on the system voltage, the internal clock signal may vary when the voltage is changed (e.g., when the memory device transitions from normal mode to a low power mode or vice versa). This may cause problems, as the internal write clock may become misaligned with the data being received on the terminal. A conventional memory device may resolve this issue by suspending access operations while the device transitions between voltage modes, however this may lead to undesirable downtimes. There may be a need to prevent data and internal write clock misalignment during voltage transitions without suspending access operations.

The present disclosure is drawn to apparatuses, systems, and methods for data operations during voltage transition. A memory device may normally operate as a double data rate device, where incoming data is latched on both the rising and falling edges of the internal write clock signal. During a voltage transition mode (e.g., when the voltage switches from high to low or low to high), the device may operate in a single data rate mode where the incoming data is latched on either the rising or falling edge. Since the data is received at roughly half the rate during the transition period, any changes to the frequency of the internal write clock will be much less likely to cause a misalignment between the data and the clock signal. Once the voltage has stabilized (e.g., finished transitioning to the new level) the device may return to a double data rate mode and latch data on both rising and falling edges of the clock signal.

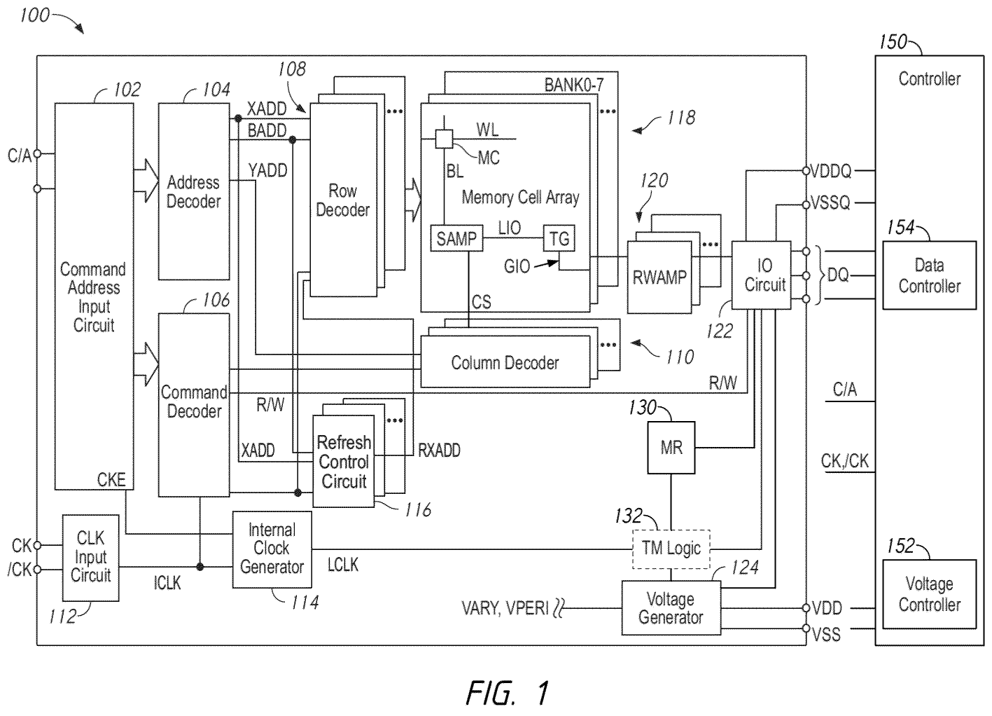

FIG. 1 is a block diagram of a semiconductor device according an embodiment of the disclosure. The semiconductor device 100 may be a semiconductor memory device, such as a DRAM device integrated on a single semiconductor chip. The device may be operated by a controller 150, such as a processor. In some embodiments, the controller 150 and memory may be packaged together. In some embodiments, the controller 150 and memory 100 may be separate components. The controller 150 includes a data controller 154 which controls a timing of data provided by the controller along a data bus and a voltage controller 152 which controls a level of one or more voltages provided to the memory 100.

The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank.

The bit lines BL are coupled to a respective sense amplifier (SAMP). Read data from the bit line BL is amplified by the sense amplifier SAMP, and transferred to a read/write amplifier circuit (RWAMP) 120 over local data lines (LIO), transfer gate (TG), and global data lines (GIO). Conversely, write data outputted from the RWAMP circuit 120 is transferred to the sense amplifier SAMP over the complementary main data lines GIO, the transfer gate TG, and the complementary local data lines LIO, and written in the memory cell MC coupled to the bit line BL.

The semiconductor device 100 may employ a plurality of external terminals, such as solder pads, that include command and address (C/A) terminals coupled to a command and address bus to receive commands and addresses, clock terminals to receive clocks CK and /CK, data terminals DQ coupled to a data bus to provide data, and power supply terminals to receive power supply potentials such as VDD, VSS, VDDQ, and VSSQ. The controller 150 may provide the data, voltages, commands, and clock signals to the memory device 100. In some embodiments, different voltages and clock signals may be used as part of different operations and/or different operational modes of the memory device 100. For example, the voltage controller 152 may provide a first level of the voltage VDD (e.g., VDD(H)) as part of a normal operational mode while a lower level of the voltage VDD (e.g., VDD(L)) may be provided as part of a low power operational mode.

The clock terminals are supplied with external clocks CK and /CK that are provided to an input circuit 112. The external clocks may be complementary. The input circuit 112 generates an internal clock ICLK based on the CK and /CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, the clock LCLK may be provided as a write clock to data receivers (e.g., input buffers) to time the receipt of write data. The input/output circuit 122 may include a number of interface connections, each of which may be couplable to one of the DQ pads (e.g., the solder pads which may act as external connections to the device 100).

In an example of receiving information, the memory device 100 may include a number of DQ terminals, each of which is coupled to a line of a data bus. The data controller 154 drives a voltage along one or more lines of the data bus in a burst of serial data along those lines. The logical state of the bit may be represented by a voltage along the line. In synchronization with the write clock LCKL, the input buffers may latch a voltage along the corresponding DQ terminal. The latched voltage may be used as the value of the received bit.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The decoded row address XADD may be used to determine which row should be opened, which may cause the data along the bit lines to be read out along the bit lines. The column decoder 110 may provide a column select signal CS, which may be used to determine which sense amplifiers provide data to the LIO. The address decoder 104 may also supply a decoded bank address BADD, which may indicate the bank of the memory array 118 containing the decoded row address XADD and column address YADD.

The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide signals which indicate if data is to be read, written, etc.

The memory includes a mode register 130 which may be used to control various aspects of the memory 100. For example, the mode register 130 may include one or more setting registers which specify various settings of the memory. Some registers may include settings which may be changed by the controller 150, for example, the controller 150 may perform a mode register write operation to set values of one or more setting registers. Some registers may be read only and may be set based on a non-volatile storage of the memory, such as a fuse setting which is loaded into the mode register at power up/reset of the memory 100. The controller 150 may perform a mode register read operation to check the value of various registers, which may contain information about various settings, conditions of the memory (e.g., temperature), error reports (e.g., error check and scrub information), other information, or combinations thereof.

The device 100 may receive an access command which is a write command. When the write command is received, and a bank address, a row address and a column address are timely supplied with the write command by the controller 150, write data supplied to the data terminals DQ by the controller 150 are provided along the data bus and written to a memory cell in the memory array 118 corresponding to the row address and column address. The controller provides a write clock to the clock terminals CK and /CK and the internal clock generator 114 generates an internal write clock (e.g., as LCLK) based on the external clock. The IO circuit 122 includes a number of data latches which latch a current voltage along a respective one of the data terminals DQ as a logical value of a bit of data in synchronization with the write clock.

The write command is received by the command decoder 106, which provides internal commands so that the write data along with any additional information (e.g., metadata) is received by data receivers in the input/output circuit 122. The controller 150 provides a write clock to the clock terminals CK and /CK, and the internal clock generator 114 provides an internal write clock LCLK which is used to time the receipt of the data along the data bus. The received data is provided from the IO circuit 122 and through the RWAMP 120 to the memory array 118 to be written into the memory cells MC which are specified by the row and column address. For example, the row decoder 108 may open a word line based on a row address, and the column decoder 110 provides a column select signal CS based on the column address which determines which bit lines receive the write data from the GIO and LIO. The data is written to the memory cells at the intersection of the active word line and bit lines.

The device 100 may receive an access command which is a read command. When a read command is received, and a bank address, a row address and a column address are timely supplied with the read command by the controller, read data is read from memory cells in the memory array 118 corresponding to the row address and column address. The read command is received by the command decoder 106, which provides internal commands so that read data buts from the memory array 118 is provided to the RWAMP 120. The read data is provided along the data bus and output to outside from the data terminals DQ via the input/output circuit 122.

The device 100 includes refresh control circuits 116 each associated with a bank of the memory array 118. Each refresh control circuit 116 may determine when to perform a refresh operation on the associated bank. The refresh control circuit 116 provides a refresh address RXADD (along with one or more refresh signals, not shown in FIG. 1). The row decoder 108 performs a refresh operation on one or more word lines associated with RXADD. The refresh control circuit 116 may perform multiple types of refresh operation, which may determine how the address RXADD is generated, as well as other details such as how many word lines are associated with the address RXADD.

The power supply terminals are supplied with power supply potentials VDD and VSS by a voltage controller 152 of the controller 150. The power supply potentials VDD and VSS are supplied to an internal voltage generator circuit 124. The internal voltage generator circuit 124 generates various internal potentials VARY, and the like based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

The operation of the internal clock generator 114 (and thus a frequency of the write clock LCLK) may depend in part on one or more voltages such as VDD received from the controller 150. For example, the internal clock generator may be operated based on the voltage VDD or one or more voltages generated therefrom by the voltage generator 124. When the controller 150 changes the voltage VDD (e.g., to transition from VDD(H) to VDD(L) or vice versa), the frequency of the internal clock signal LCLK may change relative to CK and /CK. Since the data controller 154 is providing data along the data bus with timing based on CK and /CK, this has the potential to cause a misalignment of the clock and data during a write operation while the voltage is transitioning from one level to the other.

The mode register 130 may include a transition mode setting or flag which controls a data rate at which the IO circuit 122 latches data during a write operation. When the transition mode setting is inactive, the IO circuit 122 may latch data from the DQ terminals based on a double data rate (e.g., on both rising and falling edges of a write clocks LCLK). When the transition mode setting is active, the IO circuit 122 may latch data from the DQ terminals based on a single data rate (e.g., on rising or falling edges of the write clock LCLK, but not both). In some embodiments the transition mode setting being active may change an operation of the IO circuit 122. For example, the transition mode setting may cause the input buffer so that it only responds to one edge of the clock signal LCLK. In some embodiments, a transition mode logic circuit 132 may mask one edge of the clock signal LCLK. The reduced speed of data relative to the clock may reduce or eliminate the risk of data and LCLK misalignment during the transition period.

In some embodiments, the transition mode setting may be set by the controller 150 (e.g., by performing a mode register 130 write operation) to mark the beginning of a transition period while a system voltage (e.g., VDD2) is changed by the controller 150. The data controller 154 of the controller 150 may change a rate at which data is provided along the data bus after the controller 150 sets the transition mode setting to active. In some embodiments, the controller 150 may also inactivate the transition mode setting once the voltage has transitioned. In some embodiments, the controller 150 may wait a set amount of time between activating the transition mode setting and inactivating the transition mode setting. In some embodiments, a sensor may indicate that the voltage has reached a stable level. For example, the voltage controller 152 may send a signal indicating that it has finished transitioning the voltage VDD.

In some embodiments, the memory 100 may include transition mode logic 132, which may end the transition mode. For example, the transition mode logic 132 may include a sensor which monitors a stability of the voltage VDD and the memory may send a signal indicating that the transition is done. In some embodiments the transition mode logic 132 includes a timer and the memory 100 may set the transition mode setting to inactive a set period of time has elapsed after the transition mode began.

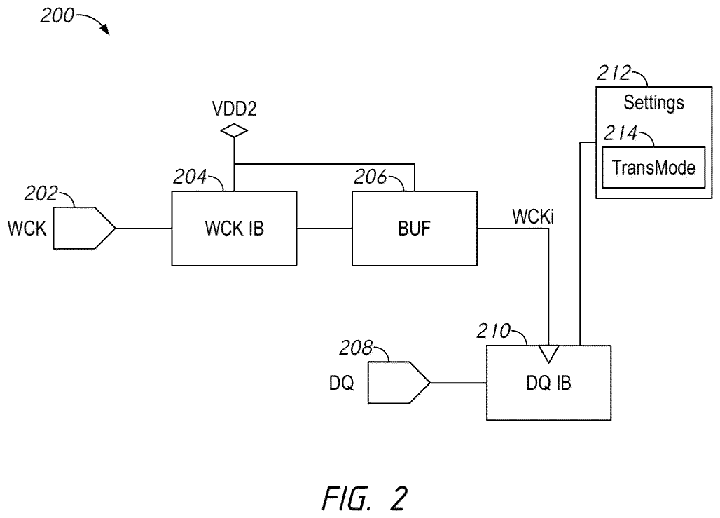

FIG. 2 is a block diagram of a write path according to some embodiments of the present disclosure. The write path 200 may, in some embodiments be included in the memory device 100 of FIG. 1. For example, the write path 200 may represent certain selected components of the clock input circuit 112, internal clock generator 114 and IO circuit 122 of FIG. 1.

The write path 200 includes a clock terminal 202 which receives a write clock WCK (e.g., CK and /CK of FIG. 1) an clock input buffer 204 (e.g., 112 of FIG. 1) which receives the input clock signal WCK and provides it to a buffer circuit 206 (e.g., 114 of FIG. 1) which in turn provides an internal write clock WCKi based on the input write clock WCK. The write pate 200 also includes a data input buffer 210 (e.g., part of the IO circuit 122 of FIG. 1) and its associated DQ terminal 208. A settings register 212 (e.g., a mode register such as 130 of FIG. 1) includes a transition mode setting TransMode 214.

The clock input buffer 204 and the buffer 206 are both coupled to a system voltage VDD2, which may be one of the voltages VDD provided by the voltage controller (e.g., 152 of FIG. 1). The buffers 204 and 206 may introduce a delay between the clock signal WCK and WCKi. The length of that delay may depend, in part, on the level of the voltage VDD2. The system may be trained for two different delays, one in a high power mode (e.g., when VDD2 is at a first level) and one in a low power mode (e.g., when VDD2 is at a low mode). The training may involve setting a variable delay circuit to match a propagation delay.

A data terminal of the input buffer 210 is coupled to the DQ terminal 208. A clock terminal is coupled to WCKi. The state of the setting TransMode 214 determines a behavior of the input buffer 210. When the setting TransMode 214 is inactive, the input buffer may latch a voltage along the DQ terminal 208 as an input bit with a double data rate. In other words, the latch 210 may latch a new value responsive to every rising and falling edge of the internal write clock WCKi. When the setting TransMode 214 is active, the latch 210 may latch a new value with a single data rate. In other words, the latch 210 may latch a new value on either rising edges or falling edges of the internal clock signal WCKi, but not both.

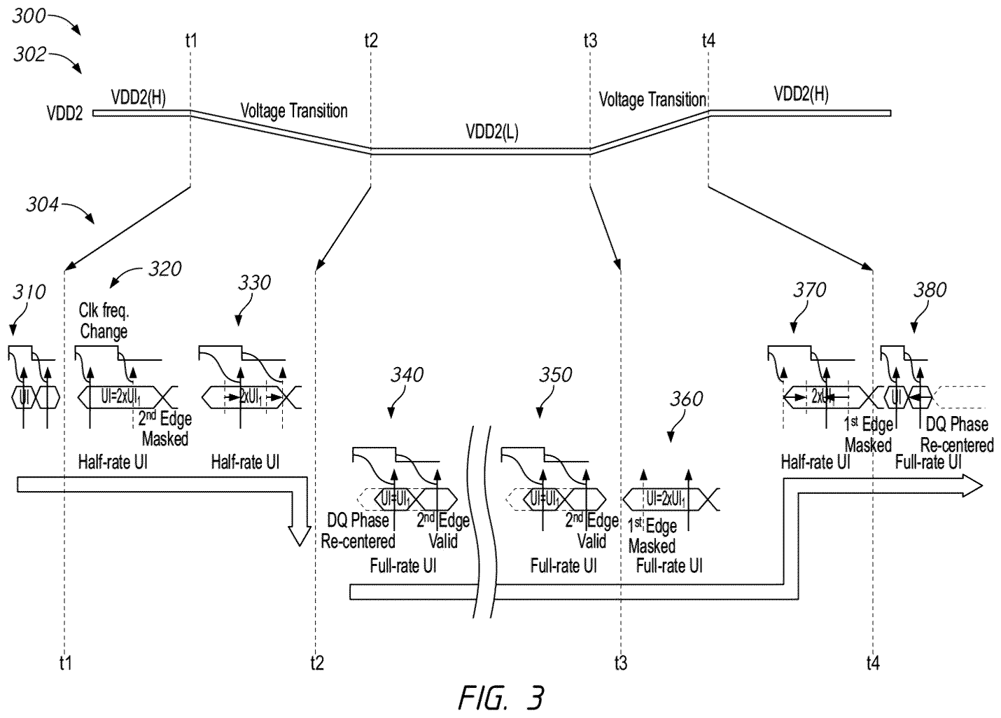

FIG. 3 is a timing chart of a voltage transition mode according to some embodiments of the present disclosure. The timing chart 300 may, in some embodiments, represent the operation a memory such as 100 of FIG. 1. The timing diagram 300 shows operations of the memory device as it goes through two transition periods, from VDD2 being a high voltage (VDD2(H)) to a low voltage (VDD2(L)) and then transitioning back to the high voltage VDD2(H).

The voltage diagram 302 shows a representation of the voltage VDD2 changing over time. Before a first time t1, the voltage is at a high level VDD2(H). Starting at t1, the controller (e.g., 150 of FIG. 1) begins transitioning the voltage from VDD2(H) to VDD2(L). At a time t2, the transition ends and the voltage reaches VDD2(L). At a third time t3, which is after t2, the controller begins transitioning the voltage from VDD2(L) back to VDD2(H), which the voltage reaches at a time t4.

The graph 304 shows a representation of a behavior of a write path of the memory (e.g., 200 of FIG. 2) before, during, and after the transition periods. A number of graphs 310-380 each show an example write clock signal and a corresponding data received along a DQ terminals. In the graphs 310-380 the write clock is shown idealized as a square wave (e.g., LCLK of FIG. 1 and/or WCKi of FIG. 2). The vertical arrows represent the point at which the data is latched by an input buffer (e.g., 210 of FIG. 2). Solid vertical lines represent points at which data is latched, and dotted vertical line represents masked clock signals which do not cause data to be latched.

Before the first time t1, the graph 310 shows that the clock signal is operating with a first frequency, and the latch is operating at a double data rate. As can be seen by the two solid vertical arrows, both bits along the DQ terminal are latched. After the time t1, as shown by the graphs 320 and 330, the clock signal's frequency begins slowing down. At the time t1, the memory enters a transition mode (e.g., responsive to a transition mode setting such as 214 of FIG. 2, being activated). Accordingly, the memory switches to a single data rate, and the falling edges of the write clock are masked. The rising edges cause the data to be latched. The controller slows down the rate at which data is transmitted to account for this. As can been by comparing graphs 320 and 330, the alignment of the clock signal relative to the incoming data may shift as the voltage changes. However, the use of the single data rate keeps the point at which the data is latched within the correct data interval.

At the time t2 the transition period ends and the transition mode setting is returned to an inactive state. As shown by the graphs 340 and 350, the clock signal has reached a stable second frequency (slower than the first frequency) and the memory has returned to a double data rate, where both rising and falling edges of the clock signal are used to latch data.

At the third time t3, a second transition period begins, this time as the voltage transitions from VDD2(L) to VDD2(H). At the time t3, the transition mode setting becomes active again and in the graph 360 and 370, a single data rate is used as the frequency of the write clock increases. At the time t4 the write clock has become stable at the first frequency and the transition mode signal is deactivated. Accordingly, at t4, the memory returns to a double date rate operation.

In this manner, the memory may continue to perform operations even while the system voltage VDD2 is changed between levels. The data rate changes during the transition period (and the frequency of the clock changes as well) but data may be written to the device throughout the process.

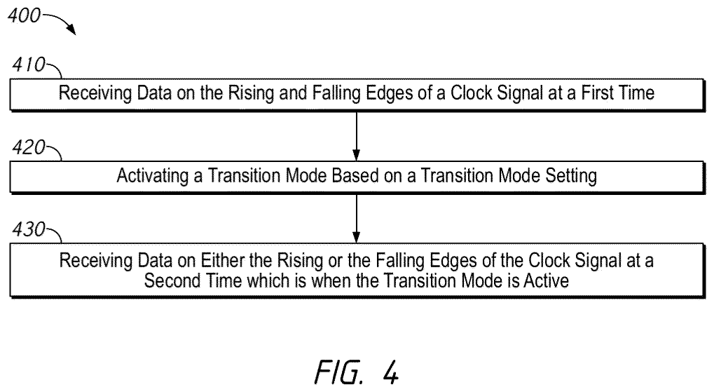

FIG. 4 is a flow chart of a method of a voltage transition mode according to some embodiments of the present disclosure. The method 400 may, in some embodiments, be implemented by one or more of the systems and apparatuses described herein. For example, the method 400 may be implemented by the memory 100 of FIG. 1 and/or the write path 200 of FIG. 2.

The method 400 may generally begin with box 410, which describes receiving data on the rising and falling edges of a clock signal at a first time. The box 410 may describe receiving data at a double data rate. The first time may be a period when a system voltage (e.g., VDD2 of FIGS. 1-3) is at a stable level (e.g., either VDD2(H) or VDD2(L)) such as before t1, between t2 and t3, or after t4 of FIG. 3. For example, the method 400 may include latching data at a data terminal (e.g., DQ terminal 208 of FIG. 2) with an input buffer (e.g., 210 of FIG. 2) at a double data rate.

Box 410 may be followed by box 420, which describes activating a transition mode based on a transition mode setting. For example, the method 400 may include receiving a mode register write command (e.g., from a controller) and setting the transition mode setting to an active state based on the mode register write command. The method 400 may include activating the transition mode setting during a period when a system voltage (e.g., VDD2) is transitioning from a first level to a second level. For example, between t1 and t2 or t3 and t4 of FIG. 2.

Box 420 may be followed by box 430, which describes receiving data on either the rising or the falling edges of the clock signal at a second time which is when the transition mode is active. Box 420 may describe receiving the data at a single data rate. The second time may be a period when the system voltage is changing such as between t1 and t2 or between t3 and t4. For example, the method 400 may include latching data in the from a data terminal in the input buffer responsive to either rising or falling edges of the clock signal. In some embodiments, the method 400 may include masking either the rising or falling edges to prevent the input buffer from responding.

The method 400 may include exiting the transition mode. For example, the method may include inactivating the transition mode setting at the end of the transition mode. In some embodiments, the method 400 may include receiving a second mode register write command (e.g., from a controller) and changing the transition mode setting to inactive based on the mode register write command. In some embodiments, the method 400 may include changing the transition mode setting to an inactive level a fixed time after setting the transition mode setting to the active level. In some embodiments, the method 400 may include determining that the system voltage has stopped transitioning (e.g., determining that the system voltage has become stable at the second level) and setting the transition mode setting to inactive based on that determination.

The method 400 may include receiving the system voltage from an external source, such as from a controller. The method 400 may include receiving the system voltage at a first level or a second level. The method 400 include receiving an external clock signal (e.g., a write clock received from a controller) and generating the clock signal (e.g., WCKi) based on the received external clock signal. The method may include generating the clock signal with a first frequency when the system voltage is at the first level and generating the clock signal with a second frequency when the system voltage is at the second level.

The method 400 may include continuing to perform operations (e.g., access operations) during the transition mode while the system voltage changes from the first level to the second level.

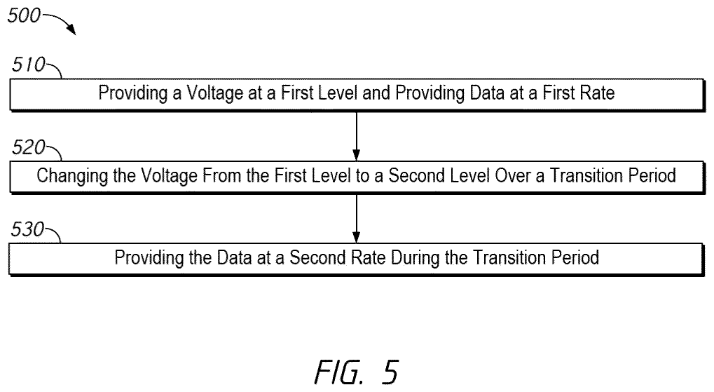

FIG. 5 is a flow chart of a method of accessing a memory during a transition mode according to some embodiments of the present disclosure. The method 500 may, in some embodiments, be implemented by one or more of the systems and apparatuses described herein. For example, the method 500 may be implemented by the controller 150 of FIG. 1.

The method 500 may generally begin with box 510, which describes providing a voltage at a first level and providing data at a first rate to a memory device. For example, the method 500 may include providing a system voltage (e.g., VDD2) and providing data. The method 500 may include providing a write clock and providing the data at a double data rate in synchronization with the write clock.

Box 510 may generally be followed by box 520, which describes changing the voltage from the first level to a second level over a transition period. For example, the controller may change the voltage from a high level (e.g., normal operations) to a low level (e.g., for a low power mode) or vice versa. The method 500 may include providing a signal to the memory to indicate that the transition period is beginning. For example, the method 500 may include performing a mode register write operation to set a transition mode setting to an active mode.

Box 520 may be followed by box 530, which describes providing the data at a second rate during the transition period. The method 500 may include providing the write clock and providing the data at a single data rate in synchronization with the write clock. For example, the method 500 may include providing the data at half the rate during the transition period than not during the transition mode. The method 500 may include performing access operations such as write operations on the memory during the transition period. For example, the method 500 may include providing write commands and addresses along with the data during the transition period.

In some embodiments, the method 500 may include providing a signal to the memory to indicate that the transition mode has ended. For example, the method 500 may include performing a second mode register write operation to set the transition mode setting to an inactive state. In some embodiments, the method 500 may include waiting a set amount of time after providing the signal to activate the transition period to send the signal to deactivate the transition period. In some embodiments, the method 500 may include sending the signal to deactivate the transition period responsive to a determination that the voltage is stable at the second level.

Of course, it is to be appreciated that any one of the examples, embodiments or processes described herein may be combined with one or more other examples, embodiments and/or processes or be separated and/or performed amongst separate devices or device portions in accordance with the present systems, devices, and methods.

Finally, the above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a data terminal configured to receive data;
a setting register configured to store a transition mode setting; and
a data input buffer configured to latch the data on both edges of an internal clock signal when the transition mode setting is inactive and configured to latch the data on one edge of the internal clock signal when the transition mode setting is active, wherein the transition mode setting is active when a system voltage is changing levels.

2. The apparatus of claim 1, further comprising:
an internal clock generator configured to provide the internal clock signal based on an external clock signal, wherein the data is received at the input terminal in synchronization with the external clock signal, and wherein a frequency of the internal clock signal is based, in part, on the level of the system voltage.

3. The apparatus of claim 1, wherein the data input buffer is configured to operate at a single data rate when the transition mode setting is active and to operate at a double data rate when the transition mode setting is inactive.

4. The apparatus of claim 1, further comprising a transition mode logic circuit configured to set the transition mode setting to an inactive level a set time after it is set to the active level.

5. The apparatus of claim 1, further comprising a transition mode logic circuit configured to set the transition mode setting to an inactive level responsive to the system voltage reaching a stable level.

6. The apparatus of claim 1, further comprising a memory array, wherein the latched data in the input buffer is written to the memory array while the system voltage is changing levels.

7. The apparatus of claim 1, wherein the setting register is a mode register.

8. A system comprising:
a controller configured to provide a voltage, a clock signal, and data; and
a memory device configured to receive the data at a double data rate relative to the clock signal in a first mode and at a single data rate relative to the clock signal in a second mode, wherein the controller is configured to put the memory device in the second mode during a transition period while changing the voltage from a first level to a second level.

9. The system of claim 8, wherein the memory device comprises a mode register configured to store a transition mode setting, wherein when the transition mode setting is active the device is in the second mode and when the transition mode setting is inactive the device is in the first mode.

10. The system of claim 9, wherein the controller is configured to perform a mode register write to set the transition mode setting to the active level at the beginning of the transition period.

11. The system of claim 8, wherein the memory device comprises an internal clock generator configured to generate an internal clock signal based on the clock signal and the voltage.

12. The system of claim 11, wherein the memory device further comprises an input buffer configured to latch the data on rising and falling edges of the internal clock signal in the first mode and on the rising or the falling edges of the internal clock signal in the second mode.

13. The system of claim 8, wherein the controller comprises a data controller configured to provide the data at a first rate while the memory device is in the first mode and configured to provide the data at a second rate while the memory device is in the second mode.

14. The system of claim 8, wherein the controller is configured to perform write operations on the memory device during the transition period.

15. A method comprising:
receiving data on the rising and falling edges of a clock signal at a first time;
activating a transition mode based on a transition mode setting; and
receiving data on either the rising or the falling edges of the clock signal at a second time when the transition mode is active.

16. The method of claim 15, further comprising receiving the data at a double data rate at the first time and receiving the data at a single data rate at the second time.

17. The method of claim 15, further comprising setting the transition mode setting to an active state to begin the transition mode.

18. The method of claim 17, further comprising setting the transition mode setting to an inactive state to end the transition mode a set time after setting the transition mode setting to the active state.

19. The method of claim 15, further comprising changing a system voltage from a first level to a second level during the transition mode.

20. The method of claim 15, further comprising writing the received data to a memory array while the transition mode is active.
